(19) United States
(12) Patent Application Publication
(10) Pub. No.: US 2019/0019943 A1
(43) Pub. Date: Jan. 17, 2019

(54) Novel magnetic tunnel junction device and magnetic random access memory

(71) Applicant: XI'AN JIAOTONG UNIVERSITY, Xi'an (CN)

(72) Inventors: Tai Min, San Jose, CA (US); Xue Zhou, Xi'an (CN); Lei Wang, Xi'an (CN)

(73) Assignee: XI'AN JIAOTONG UNIVERSITY

(21) Appl. No.: 16/120,584

(22) Filed: Sep. 4, 2018

(30) Foreign Application Priority Data
Jul. 26, 2018 (CN) 201810837874.0

(51) Int. Cl. H01L 43/02; H01L 27/22; H01L 43/10

(52) U.S. Cl. CPC H01L 43/02; H01L 43/10; H01L 27/228

(57) ABSTRACT

A magnetic tunnel junction device and a magnetic random access memory based on a synthetic antiferromagnetic pinned layer are disclosed, relating to a multilayer structure which is suitable for a pinned layer, namely a synthetic antiferromagnetic device. Antiferromagnetic coupling of the synthetic antiferromagnetic device can be enhanced by electric field. The synthetic antiferromagnetic device can be used as a pinned layer of the magnetic tunnel junction, and the antiferromagnetic coupling is enhanced under the electric field to ensure that a ferromagnetic layer, which is close to a barrier layer, of the pinned layer will not be switched, thereby achieving stable data writing. The magnetic random access memory is formed by the magnetic tunnel junction based on the synthetic antiferromagnetic pinned layer, has advantages such as, high density, low power consumption, high speed, radiation resistance and non-volatility.

### CROSS REFERENCE OF RELATED APPLICATION

The present invention claims priority under 35 U.S.C. 119(a-d) to CN 201810837874.0, filed Jul. 26, 2018.

### BACKGROUND OF THE PRESENT INVENTION

### Field of invention

The present invention relates to circuits and devices having magnetic/ferromagnetic materials or structures and applications thereof, and more particularly to an electrical-assist-controlled magnetic random access memory based on a synthetic antiferromagnetic pinned layer and using an electric field for auxiliary erasing.

### Description of Related Arts

A magnetic tunnel junction (MTJ) consists of two magnetic metal layers (such as iron, cobalt, nickel) and an ultra-thin insulating layer (such as alumina or magnesia) sandwiched between two magnetic metal layers. If a bias voltage is applied between the two magnetic metal layers, since the insulating layer is thin, electrons can pass through the barrier through the tunneling effect. With a given bias voltage, the magnitude of the tunneling current/breakthrough resistance depends on the relative orientation of the magnetization in the two ferromagnetic layers. This phenomenon is called tunneling magnetoresistance (TMR), which indicates that spin depends on the tunneling effect. The relative orientation of the magnetization in the two ferromagnetic layers can be varied by the applied magnetic field.

Conventionally, magnetic junctions MT, including MTJ and spin valve) are commonly used in magnetic random access memories. Magnetic random access memories have attracted great attention in the industrial field due to their advantages such as non-volatility, excellent durability, high read/write speed, and low power consumption. A magnetoresistive element in a magnetic random access memory (MRAM) may be a magnetic junction including two or more ferromagnetic films. The resistance of the MJ depends on the relative orientation of the magnetization of the pinned magnetic layer and the free magnetic layer. The magnetic moment of the free magnetic layer (FL) can be switched between two stable orientations, and the resistance of the MJ presents two values under two relative magnetic orientations of the pinned magnetic layer and the free magnetic layer, which can be used to represent the binary states “1” and “0” of the data states and applied to the binary logic. The free layer magnetization orientation of the magnetic junction can be changed by an external magnetic field to obtain a low resistance state (“1”) or a high resistance state (“0”) corresponding to the parallel or antiparallel magnetization of the free magnetic layer and the pinned magnetic layer, so as to obtain “1”/“0” state required by the logic circuit.

One type of MRAM is a spin transfer torque-magnetic random access memory (STT-MRAM). Using the action of the spin-polarized current (spin torque) on the magnetic moment, the magnetization direction of the free magnetic layer can be changed, and the magnetization direction of the free magnetic layer is switched by changing the direction of the current, thereby completing MJ data writing in the STT-MRAM. However, the spin-polarized current applied to the spin-transfer torque-random access memory is generally around 10₇ A/cm², and the larger spin-polarized current limits the arrangement density of the memory cell array. As the density of the memory cell array keeps increasing, the cell size continues to reduce, causing the magnetization of the pinned layer becomes unstable under the writing spin polarized current.

In order to solve this problem, an electric-field-assist-controlled magnetic random storage device based on a synthetic antiferromagnetic pinned layer is provided, which uses an electric field to control a synthetic antiferromagnetic force to enhance its antiferromagnetic coupling, so as to be a magnetic tunnel junction of the pinned layer which can maintain the antiferromagnetic state under the action of writing spin polarized current.

### SUMMARY OF THE PRESENT INVENTION

An object of the present invention is to provide one type of spin transfer torque-magnetic random access memory (STT-MRAM). According to “Low voltage switching of magnetism through ionic liquid gating control of RKKY interaction in FeCoB/Ru/FeCoB and (Pt/Co)2/Ru/(Co/Pt)2multilayers” on Nature Communication, the applicants' article reports that an SAF (Synthetic Antiferromagnetic) multilayer structure is controlled by an electric field to enhance antiferromagnetic coupling of the SAF multilayer structure. The present invention provides the spin transfer torque-magnetic random access memory, wherein by combining synthetic antiferromagnetic and magnetic tunnel junctions, the synthetic antiferromagnetic SAF is used as a pinned magnetic layer of a magnetic tunnel junction for enhancing antiferromagnetic coupling of the synthetic antiferromagnetic SAF by electric field control, and ensuring that the pinned layer maintains an antiferromagnetic state while the current is applied, wherein a thickness of a ferromagnetic layer near a barrier layer can be small. Therefore, the spin transfer torque-magnetic random access memory is called an electric-field-assist-controlled magnetic random access device based on a synthetic antiferromagnetic pinned layer, and the device performs stable data writing under the action of both an electric field and a current. In addition, electric field assisted control enhances the antiferromagnetic coupling of the pinned layer, providing advantages of high density, high speed, and low power consumption.

Accordingly, in order to accomplish the above objects, the present invention provides:

A synthetic antiferromagnetic device, having a stacked structure, comprises the first ferromagnetic layer, the second ferromagnetic layer and the nonmagnetic spacer layer arranged therebetween, wherein the first ferromagnetic layer, the second ferromagnetic layer and the nonmagnetic spacer layer form the stack structure of the first ferromagnetic layer, the nonmagnetic spacer layer and the second ferromagnetic layer in sequence; and the stack structure is equivalent to the synthetic antiferromagnetic device;

wherein the synthetic antiferromagnetic device is under an antiferromagnetic state; when the synthetic antiferromagnetic device adopts a material of a different type, a different thickness or a different interface disorder, an antiferromagnetic coupling strength is enhanced as an applied electric field strength increases; meanwhile, the ferromagnetic layer is difficult to be switched under an applied current.

Preferably, the synthetic antiferromagnetic device is circular and has a diameter of 1 nm-100 nm; a voltage of the applied electric field is 0.1-15V; wherein materials of the first ferromagnetic layer and the second ferromagnetic layer comprises but not limited to CoFeB and [Pt/Co]ₙ multilayer; and a material of the nonmagnetic spacer layer comprises but not limited to Ru with a thickness of 0.1 nm-10 nm.

Preferably, the first ferromagnetic layer and the second ferromagnetic layer are perpendicular to the layer interface.

Preferably, the first ferromagnetic layer and the second ferromagnetic layer are parallel to the layer interface.

The invention further provides a magnetic tunnel junction device based on a synthetic antiferromagnetic pinned layer, comprising: a free magnetic layer, a pinned magnetic layer based on a synthetic antiferromagnetic device, and a nonmagnetic barrier layer, wherein the nonmagnetic barrier layer is arranged between the free magnetic layer and the pinned magnetic layer based on the synthetic antiferromagnetic device; magnetization directions of the pinned magnetic layer based on the synthetic antiferromagnetic device and the free magnetic layer are outwardly perpendicular or parallel to interface;

wherein the pinned magnetic layer based on the synthetic antiferromagnetic device has a stack structure of a first ferromagnetic layer, a nonmagnetic spacer layer and a second ferromagnetic layer in sequence;

the magnetic tunnel junction device further comprises a first electrode and a second electrode, wherein the first electrode and the second electrode respectively contact with a bottom ferromagnetic layer of the free magnetic layer and a bottom ferromagnetic layer of the pinned magnetic layer based on the synthetic antiferromagnetic device, so as to conduct a current in the magnetic tunnel junction device.

Preferably, a ferromagnetic layer material of the pinned magnetic layer based on the synthetic antiferromagnetic device is selected from but not limited to Fe, Co, CoFe, Ni, CoCrPt, CoFeB, (Co/Ni)ₚ, (Co/Pd)ₘ or (Co/Pt)ₙ, wherein m, n and p refer to repetition numbers of stack;

wherein a nonmagnetic spacer layer material of the pinned magnetic layer based on the synthetic antiferromagnetic device is selected from but not limited to a group consisting of Nb, Ta, Cr, Mo, W, Re, Ru, Os, Rh, Ir, Pt, Cu, Ag and Au.

Preferably, the free magnetic layer is made of a ferromagnetic or ferrimagnetic metal and an alloy thereof; the free magnetic layer is selected from but not limited to Fe, Co, Ni, Mn, NiFe, FePd, FePt, CoFe, CoPd, CoPt, YCo, LaCo, PrCo, NdCo, SmCo, CoFeB, BiMn or NiMnSb, and a combination thereof with a material selected form a group consisting of B, Al, Zr, Hf, Nb, Ta, Cr, Mo, Pd or Pt.

Preferably, the free magnetic layer is made of a synthetic ferromagnetic or ferrimagnetic material which is made from but not limited to Co/Ir, Co/Pt, Co/Pd, CoCr/Pt, Co/Au or Ni/Co multilayer with a 3d/4d/4f/5d/5f rare earth metal layer stacked synthetic structure.

Preferably, the free magnetic layer is made of a semi-metallic ferromagnetic material comprising a Heusler alloy in a form of XYZ or X₂YZ, wherein X is selected from but not limited to a group consisting of Mn, Fe, Co, Ni, Pd and Cu; Y is selected from but not limited to a group consisting of Ti, V, Cr, Mn, Fe, Co, and Ni; and Z is selected from but not limited to a group consisting of Al, Ga, In, Si, Ge, Sn and Sb.

Preferably, the free magnetic layer is made of a synthetic antiferromagnetic material, which is formed by a ferromagnetic layer and a spacer layer, wherein a ferromagnetic layer material of the free magnetic layer is selected from but not limited to Fe, Co, CoFe, Ni, CoCrPt, CoFeB, (Co/Ni)ₚ, (Co/Pd)ₘ or (Co/Pt)ₙ, wherein m, n and p refer to repetition numbers of stack; and a spacer layer material of the free magnetic layer is selected from but not limited to a group consisting of Nb, Ta, Cr, Mo, W, Re, Ru, Os, Rh, Ir, Pt, Cu, Ag and Au.

Preferably, the nonmagnetic spacer layer is made of an oxide, a nitride or an oxynitride, and an element of the oxide, the nitride or the oxynitride material is selected from but not limited to a group consisting of Mg, B, Al, Ca, Sr, La, Ti, Hf, V, Ta, Cr, W, Ru, Cu, In, Si and Eu.

Preferably, the nonmagnetic spacer layer is made of a metal or an alloy, and an element of the metal or alloy is selected from but not limited to a group consisting of Cu, Ag, Au, Al, Pt, Ta, Ti, Nb, Os, Ru, Rh, Y, Mg, Pd, Cr, W, Mo and V.

Preferably, the nonmagnetic spacer layer is made of but not limited to SiC or a ceramic material.

Preferably, an electrode material is a metal material or an alloy material selected from but not limited to a group consisting of Li, Mg, Al, Ca, Sc, Ti, V, Mn, Cu, Zn, Ga, Ge, Sr, Y, Zr, Nb, Mo, Tc, Ru, Rh, Pd, Ag, Cd, In, Sn, Sb, Ba, Hf, Ta, W, Re, Os, Ir, Pt, Au, Ti, Pb, Bi, Po, La, Ce, Pr, Nd, Pm, Sm, Eu, Gd, Tb, Dy, Ho, Er, Tm and Yb.

Preferably, the electrode material is made from a carbon-based conductive material which is but not limited to graphite, carbon nanotubes or bamboo charcoal.

The present invention also provides a magnetic random access memory based on a synthetic antiferrotnagnetic pinned layer, comprising:

an electric-field-assist-controlled magnetic tunnel junction device, which comprises a free magnetic layer, a pinned magnetic layer based on a synthetic antiferromagnetic device, and a nonmagnetic barrier layer arranged therebetween; wherein magnetization directions of the pinned magnetic layer based on the synthetic antiferromagnetic device and the free magnetic layer are outwardly perpendicular or parallel to interface; the synthetic antiferromagnetic device enhances antiferromagnetic coupling by electric field control;

the magnetic random access memory further comprises a pair of parallel electrode plates which generate an electric field, wherein the parallel electrode plates are arranged at both ends of the magnetic tunnel junction; an insulating layer is provided between the parallel electrode plates and electrodes; the parallel electrode plates generate the electric field with an external power source; the synthetic antiferromagnetic device enhances the antiferromagnetic coupling of the pinned layer under the electric field.

Beneficial effects of the present invention:

The synthetic antiferromagnetic device is used as the pinned layer of the magnetic tunnel junction, so as to form the stack structure of the free magnetic layer, the nonmagnetic barrier layer and the synthetic antiferromagnetic device in sequence; the pinned magnetic layer based on the synthetic antiferromagnetic device enhances the antiferromagnetic coupling under electric field control, so as to ensure that the ferromagnetic layer, which is close to the barrier layer, of the pinned layer based on the synthetic antiferromagnetic device is not switched under external conditions.

The magnetic tunnel junction is applied to the magnetic random access memory, wherein the antiferromagnetic coupling strength of the pinned layer based on the synthetic antiferromagnetic is enhanced by electric field control, and the magnetization direction is not changed with the current, so that the data is stably written. At this time, a thickness of the ferromagnetic layer of the pinned layer can be reduced, thereby reducing a device volume and increasing an arrangement density of a memory cell array. Stable data writing is achieved by interaction of the electric field and the current, and the structure is simple with advantages of high density, low power consumption, high speed, radiation resistance and non-volatility.

The present invention is characterized in that: 1) the antiferromagnetic coupling strength of the synthetic antiferromagnetic pinned layer is enhanced by the electric field, thereby reducing the thickness of the pinned layer to reduce the device volume and increasing the arrangement density of the memory cell array; 2) the present invention uses the synthetic antiferromagnetic device as the pinned layer of the magnetic tunnel is junction, wherein the synthetic antiferromagnetic device has a strong anti-interference ability, which will further develop an application range of spintronic devices and promote development of novel memory industry.

### BRIEF DESCRIPTION OF THE DRAWINGS

Drawings are described herein to provide a further understanding of the present invention, and constitute a part thereof, which do not constitute an improper limitation of the present invention.

FIG. 1 illustrates variation of an antiferromagnetic coupling strength J of a synthetic antiferromagnetic device under voltage control.

FIG. 2 is a sketch view of a perpendicular magnetic anisotropy magnetic tunnel junction device based on a synthetic antiferromagnetic pinned layer.

FIG. 3(a) illustrates antiferromagnetic coupling of a synthetic antiferromagnetic pinned layer is enhanced under an electric field, a magnetic tunnel junction free layer is switched by applied a first direction current, while the pinned layer maintains an antiferromagnetic state, so as to realizing stable data writing.

FIG. 3(b) illustrates reading magnetic tunnel junction data with a direction current when no electric field is applied.

FIG. 4(a) illustrates antiferromagnetic coupling of a synthetic antiferromagnetic pinned layer is enhanced under an electric field, a magnetic tunnel junction free layer is switched by applied a second direction current, while the pinned layer maintains an antiferromagnetic state, so as to realizing stable data writing.

FIG. 4(b) illustrates reading magnetic tunnel junction data with a direction current when no electric field is applied.

FIG. 5 is a sketch view of an electric-field-assist-controlled magnetic random access memory based on a synthetic antiferromagnetic pinned layer.

### DETAILED DESCRIPTION OF THE PREFERRED EMBODIMENT

Referring to the accompanying drawings and embodiments, technical solution of the present invention will be described in detail below. The following embodiments relate to a magnetic random access memory for enhancing antiferromagnetic coupling of a synthetic antiferromagnetic pinned layer by electric field control, which are exemplary only and not intended to be limiting.

FIG. 1 illustrates variation of an antiferromagnetic coupling strength J of a synthetic antiferromagnetic device under voltage control, which is described in paper “Low voltage switching of magnetism through ionic liquid gating control of RKKY interaction in FeCoB/Ru/FeCoB and (Pt/Co)2/Ru/(Co/Pt)2 multilayers”. When a ferromagnetic layer is [Pt (0.88 nm)|(Co(0.70 nm)]₂, an interface disorder is 0.5, and a thickness of Ru is 0.66 nm, the synthetic antiferromagnetic device has relatively weak antiferromagnetic coupling in an initial state, and the antiferromagnetic coupling can be enhanced when an applied electric field is increased to 4V. It can be seen from FIG. 1 that as a voltage increases, the antiferromagnetic coupling strength J changes from the initial—1.9 erg/cm² to −4 erg/cm², which means the antiferromagnetic coupling is enhanced with the voltage. At this time, the ferromagnetic layer is difficult to by switched under an applied current.

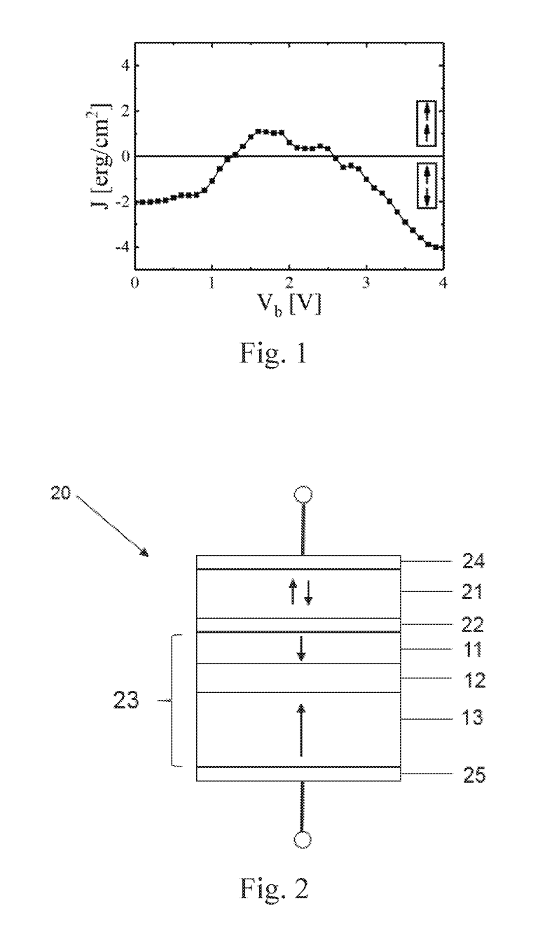

FIG. 2 illustrates a magnetic tunnel junction device 20 based on a synthetic antiferromagnetic pinned layer formed by a perpendicular anisotropic magnetic tunnel junction and a synthetic antiferromagnetic device. FIG. 2 and other figures of the present invention are not drawn according to relative scale. The magnetic tunnel junction device 20 comprises a free magnetic layer 21, a pinned magnetic layer 23 based on a synthetic antiferromagnetic device, and a nonmagnetic barrier layer 22 arranged therebetween; magnetization directions of the pinned magnetic layer 23 based on the synthetic antiferromagnetic device and the free magnetic layer 21 are basically perpendicular to interface.

According to an embodiment, the pinned magnetic layer 23 based on the synthetic antiferromagnetic device is made of a synthetic antiferromagnetic (SAF) material, with a structure of a first ferromagnetic layer 11, a nonmagnetic spacer layer 12 and a second ferromagnetic layer 13 in sequence. The synthetic antiferromagnetic device is circular and has a diameter of 1 nm-100 nm; a voltage of the applied electric field is 0.1-15V. Materials of the first ferromagnetic layer and the second ferromagnetic layer comprises but not limited to CoFeB and [Pt/Co]ₙ multilayer; and a material of the nonmagnetic spacer layer comprises but not limited to Ru with a thickness of 0.1 nm-10 nm. The first ferromagnetic layer and the second ferromagnetic layer are perpendicular or parallel to interface.

A ferromagnetic layer material of the pinned magnetic layer based on the synthetic antiferromagnetic device is selected from but not limited to Fe, Co, CoFe, Ni, CoCrPt, CoFeB, (Co/Ni)ₚ, (Co/Pd)ₘ or (Co/Pt)ₙ, wherein m, n and p refer to repetition numbers of stack; a nonmagnetic spacer layer material of the pinned magnetic layer based on the synthetic antiferromagnetic device is selected from but not limited to a group consisting of Nb, Ta, Cr, Mo, W, Re, Ru, Os, Rh, Ir, Pt, Cu, Ag and Au.

In the present embodiment, the free magnetic layer 21 is made of a ferromagnetic or ferrimagnetic metal and an alloy thereof; the free magnetic layer is selected from but not limited to Fe, Co, Ni, Mn, NiFe, FePd, FePt, CoFe, CoPd, CoPt, YCo, LaCo, PrCo, NdCo, SmCo, CoFeB, BiMn or NiMnSb, and a combination thereof with a material selected form a group consisting of B, Al, Zr, Hf, Nb, Ta, Cr, Mo, Pd or Pt.

In alternative embodiments, the free magnetic layer 21 is made of a semi-metallic ferromagnetic material comprising a Heusler alloy in a form of XYZ or X₂YZ, wherein X is selected from but not limited to a group consisting of Mn, Fe, Co, Ni, Pd and Cu; Y is selected from but not limited to a group consisting of Ti, V, Cr, Mn, Fe, Co, and Ni; and Z is selected from but not limited to a group consisting of Al, Ga, In, Si, Ge, Sn and Sb.

In alternative embodiments, the free magnetic layer is made of a synthetic antiferromagnetic (SAF) material, which is formed by a ferromagnetic layer and a spacer layer, wherein a ferromagnetic layer material of the free magnetic layer is selected from but not limited to Fe, Co, CoFe, Ni, CoCrPt, CoFeB, (Co/Ni)ₚ, (Co/Pd)ₘ or (Co/Pt)ₙ, wherein m, n and p refer to repetition numbers of stack; and a spacer layer material of the free magnetic layer is selected from but not limited to a group consisting of Nb, Ta, Cr, Mo, W, Re, Ru, Os, Rh, Ir, Pt, Cu, Ag and Au.

In the present embodiment, the free magnetic layer 21 and the pinned magnetic layer 23 based on a synthetic antiferromagnetic device are conductive.

In alternative embodiments, the nonmagnetic barrier layer 22 is an insulating tunnel barrier layer, and the nonmagnetic spacer layer 22 is made of an oxide, a nitride or an oxynitride, and an element of the oxide, the nitride or the oxynitride material is selected from but not limited to a group consisting of Mg, B, Al, Ca, Sr, La, Ti, Hf, V, Ta, Cr, W, Ru, Cu, In, Si and Eu.

In alternative embodiments, the nonmagnetic barrier layer 22 is a conductive layer, and the nonmagnetic spacer layer 22 is made of a metal or an alloy, and an element of the metal or alloy is selected from but not limited to a group consisting of Cu, Ag, Au, Al, Pt, Ta, Ti, Nb, Os, Ru, Rh, Y, Mg, Pd, Cr, W, Mo and V.

In alternative embodiments, the nonmagnetic spacer layer is made of SiC, C or a ceramic material.

In alternative embodiments, the nonmagnetic barrier layer 22 may adopts other structures, such as a granular layer including conductive channels in an insulating matrix as shown in “Method and system for providing a magnetic tunneling junction using spin-orbit interaction based switching and memories utilizing the magnetic tunneling junction” (U.S. Pat. No. 9,076,537).

In the above embodiment, the free magnetic layer 21 and the pinned magnetic layer 23 made of different materials are ferromagnetic, and the insulating tunnel barrier layer 22 is nonmagnetic.

As shown in FIG. 2, a first electrode 25 is in contact with the pinned magnetic layer 23 based on the synthetic antiferromagnetic device, and a second electrode 24 is in contact with the free magnetic layer 21, wherein the first electrode 25 and the second electrode 24 are connected to a control circuit, so as to provide a read or write current to a magnetic tunnel junction structure. Meanwhile, the magnetic tunnel junction device 20 is connected to the control circuit through the first electrode 25 and the second electrode 24. The first electrode 25 and the second electrode 24 may be made of one conductive material selected from but not limited to a group consisting of Li, Mg, Al, Ca, Sc, Ti, V, Mn, Cu, Zn, Ga, Ge, Sr, Y, Zr, Nb, Mo, Tc, Ru, Rh, Pd, Ag, Cd, In, Sn, Sb, Ba, Hf, Ta, W, Re, Os, Ir, Pt, Au, Tl, Pb, Bi, Po, La, Ce, Pr, Nd, Pm, Sm, Eu, Gd, Tb, Dy, Ho, Er, Tm and Yb. In alternative embodiments, the conductive material is a carbon-based conductive material selected from but not limited to graphite, carbon nanotubes or bamboo charcoal.

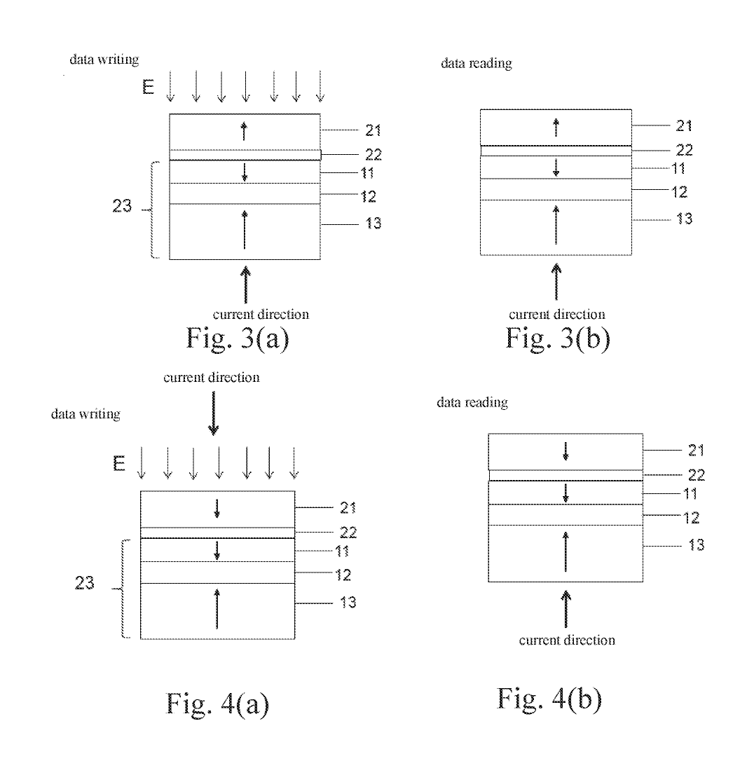

FIG. 3(a) illustrates antiferromagnetic coupling of a synthetic antiferromagnetic pinned layer is enhanced under an electric field, a magnetic tunnel junction free layer is switched by applied a first direction current, while the pinned layer maintains an antiferromagnetic state, so as to realizing stable data writing. When a current I passes through the magnetic tunnel junction from the pinned magnetic layer 23 based on the synthetic antiferromagnetic device to the free magnetic layer 21 through the electrodes, the magnetization direction of the ferromagnetic layer 11 in the pinned magnetic layer 23 based on the synthetic antiferromagnetic device is contrast to a magnetization direction of the free magnetic layer 21, and a data writing state is “0”. FIG. 3(b) illustrates reading magnetic tunnel junction data of the pinned layer 23 based on the synthetic antiferromagnetic device with a direction current when no electric field is applied, wherein TMR between the ferromagnetic layer 11 and the free layer 21 in the magnetic tunnel junction plays a leading role, in such a manner that the ferromagnetic layer 11 and the free layer 21 have opposite magnetization directions, and a data reading state is “0”.

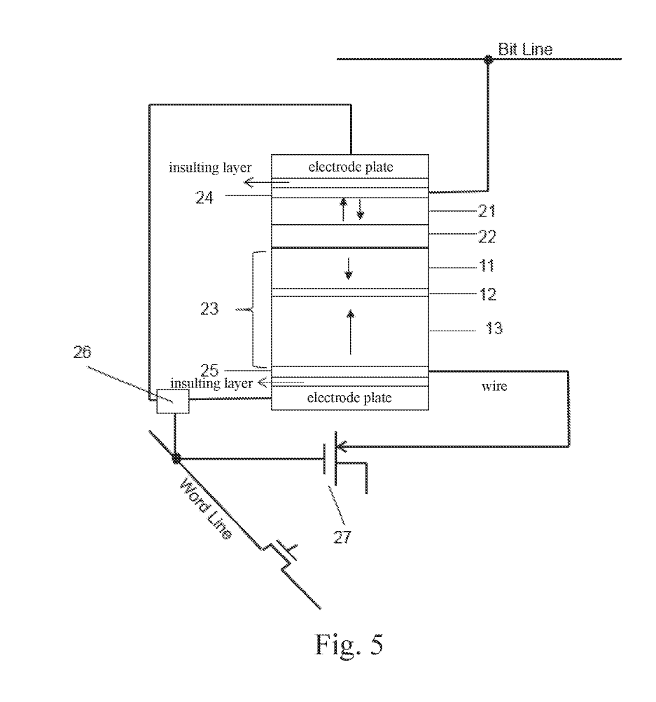

FIG. 4(a) illustrates antiferromagnetic coupling of a synthetic antiferromagnetic pinned layer is enhanced under an electric field, a magnetic tunnel junction free layer is switched by applied a second direction current, while the pinned layer maintains an antiferromagnetic state, so as to realizing stable data writing. When a current I passes through the magnetic tunnel junction from the free magnetic layer 21 to the pinned magnetic layer 23 based on the synthetic antiferromagnetic device through the electrodes, the magnetization direction of the ferromagnetic layer 11 in the pinned magnetic layer 23 based on the synthetic antiferromagnetic device is identical to a magnetization direction of the free magnetic layer 21, and a data writing state is “1”. FIG. 4(b) illustrates reading magnetic tunnel junction data of the pinned layer 23 based on the synthetic antiferromagnetic device with a direction current when no electric field is applied, wherein TMR between the ferromagnetic layer 11 and the free layer 21 in the magnetic tunnel junction plays a leading role, in such a manner that the ferromagnetic layer 11 and the free layer 21 have same magnetization directions, and a data reading state is “1”.

FIG. 5 illustrates a magnetic random access memory formed by a magnetic tunnel junction 20, a first electrode 25, a second electrode 24, and parallel electrode plates, comprising: an electric-field-assist-controlled magnetic tunnel junction device, which comprises a free magnetic layer 21, a pinned magnetic layer 23 based on a synthetic antiferromagnetic device, and a nonmagnetic barrier layer 22 arranged therebetween; wherein magnetization directions of the pinned magnetic layer based on the synthetic antiferromagnetic device and the free magnetic layer are outwardly perpendicular or parallel to interface; the synthetic antiferromagnetic device enhances antiferromagnetic coupling by electric field control.

The magnetic random access memory further comprises a pair of parallel electrode plates which generate an electric field, wherein the parallel electrode plates are arranged at both ends of the magnetic tunnel junction; an insulating layer is provided between the parallel electrode plates and electrodes; the parallel electrode plates generate the electric field with an external power source; the synthetic antiferromagnetic device enhances the antiferromagnetic coupling pinnedunder the electric field.

The device can be controlled by an electric field to enhance antiferromagnetic coupling of the pinned magnetic layer 23 based on the synthetic antiferromagnetic device. The parallel electrode plates are connected to an external circuit voltage controller 26. The magnetic tunnel junction 20 comprises the free magnetic layer 21, the nonmagnetic barrier layer 22, and the pinned magnetic layer 23 based on the synthetic antiferromagnetic device. The magnetic tunnel junction 20 is connected to a bit line through the metal electrode 24, and is connected to a word line and a transistor 27 through the metal electrode 25. While the current passes through the magnetic tunnel junction, the voltage controller 26 can quickly supply voltage to the parallel electrode plates for generating an electric field, so that the antiferromagnetic coupling of the pinned magnetic layer 23 based on the synthetic antiferromagnetic device is enhanced to reduce a thickness of the ferromagnetic layer 11 and maintain a magnetization direction, thereby reducing a memory cell volume and increasing an arrangement density of the memory cell array.

The present invention is not limited to the above embodiments. Based on the technical solutions disclosed by the present invention, those skilled in the art can make some substitutions for some of the technical features without any creative labor according to the disclosed technical content. Such substitutions and modifications are within the scope of the present invention.

What is claimed is:

1. A synthetic antiferromagnetic device comprises:
a first ferromagnetic layer, a second ferromagnetic layer and a nonmagnetic spacer layer arranged therebetween, wherein the first ferromagnetic layer, the second ferromagnetic layer and the nonmagnetic spacer layer form a stack structure of the first ferromagnetic layer, the nonmagnetic spacer layer and the second ferromagnetic layer in sequence; and the stack structure is equivalent to the synthetic antiferromagnetic device;
wherein the synthetic antiferromagnetic device is under an antiferromagnetic state; when the synthetic antiferromagnetic device adopts a material of a different type, a different thickness or a different interface disorder, an antiferromagnetic coupling strength is enhanced as an applied electric field strength increases; meanwhile, the ferromagnetic layer is difficult to be switched under an applied current.

2. The synthetic antiferromagnetic device, as recited in claim 1, wherein the synthetic antiferromagnetic device is circular and has a diameter of 1 nm-100 nm; a voltage of the applied electric field is 0.1-15V;
wherein materials of the first ferromagnetic layer and the second ferromagnetic layer comprises but not limit to CoFeB and [Pt/Co]ₙ multilayer; and a material of the nonmagnetic spacer layer comprises but not limit to Ru with a thickness of 0.1 nm-10 nm.

3. The synthetic antiferromagnetic device, as recited in claim 1, wherein the first ferromagnetic layer and the second ferromagnetic layer are perpendicular to interface.

4. The synthetic antiferromagnetic device, as recited in claim 1, wherein the first ferromagnetic layer and the second ferromagnetic layer are parallel to interface.

5. A magnetic tunnel junction device based on a synthetic antiferromagnetic pinned layer, comprising:
a free magnetic layer, a pinned magnetic layer based on a synthetic antiferromagnetic device, and a nonmagnetic barrier layer, wherein the nonmagnetic barrier layer is arranged between the free magnetic layer and the pinned magnetic layer based on the synthetic antiferromagnetic device; magnetization directions of the pinned magnetic layer based on the synthetic antiferromagnetic device and the free magnetic layer are outwardly perpendicular or parallel to interface;
wherein the pinned magnetic layer based on the synthetic antiferromagnetic device has a stack structure of a first ferromagnetic layer, a nonmagnetic spacer layer and a second ferromagnetic layer in sequence;
the magnetic tunnel junction device further comprises a first electrode and a second electrode, wherein the first electrode and the second electrode respectively contact with the free magnetic layer and a bottom ferromagnetic layer of the pinned magnetic layer based on the synthetic antiferromagnetic device, so as to conduct a current in the magnetic tunnel junction device.

6. The magnetic tunnel junction device, as recited in claim 5, wherein a ferromagnetic layer material of the pinned magnetic layer based on the synthetic antiferromagnetic device is selected from but not limited to Fe, Co, CoFe, Ni, CoCrPt, CoFeB, (Co/Ni)ₚ, (Co/Pd)ₘ or (Co/Pt)ₙ, wherein m, n and p refer to repetition numbers of stack;
wherein a nonmagnetic spacer layer material of the pinned magnetic layer based on the synthetic antiferromagnetic device is selected from but not limited to a group consisting of Nb, Ta, Cr, Mo, W, Re, Ru, Os, Rh, Ir, Pt, Cu, Ag and Au.

7. The magnetic tunnel junction device, as recited in claim 5, wherein:
the free magnetic layer is made of a ferromagnetic or ferrimagnetic metal and an alloy thereof; the free magnetic layer is selected from but not limited to Fe, Co, Ni, Mn, NiFe, FePd, FePt, CoFe, CoPd, CoPt, YCo, LaCo, PrCo, NdCo, SmCo, CoFeB, BiMn or NiMnSb, and a combination thereof with a material selected form a group consisting of B, Al, Zr, Hf, Nb, Ta, Cr, Mo, Pd or Pt;
or the free magnetic layer is made of a synthetic ferromagnetic or ferrimagnetic material which is selected from but not limited to Co/Ir, Co/Pt, Co/Pd, CoCr/Pt, Co/Au or Ni/Co multilayer with a 3d/4d/4f/5d/5f rare earth metal layer stacked synthetic structure;
or the free magnetic layer is made of a semi-metallic ferromagnetic material comprising a Heusler alloy in a form of XYZ or X₂YZ, wherein X is selected from but not limited to a group consisting of Mn, Fe, Co, Ni, Pd and Cu; Y is selected from but not limited to a group consisting of Ti, V, Cr, Mn, Fe, Co, and Ni; and Z is selected from but not limited to a group consisting of Al, Ga, In, Si, Ge, Sn and Sb;
or the free magnetic layer is made of a synthetic antiferromagnetic material, which is formed by a ferromagnetic layer and a spacer layer, wherein a ferromagnetic layer material of the free magnetic layer is selected from but not limited to Fe, Co, CoFe, Ni, CoCrPt, CoFeB, (Co/Ni)ₚ, (Co/Pd)ₘ or (Co/Pt)ₙ, wherein m, n and p refer to repetition numbers of stack; and a spacer layer material of the free magnetic layer is selected from but not limited to a group consisting of Nb, Ta, Cr, Mo, W, Re, Ru, Os, Rh, Ir, Pt, Cu, Ag and Au.

8. The magnetic tunnel junction device, as recited in claim 5, wherein:
the nonmagnetic spacer layer is made of an oxide, a nitride or an oxynitride, and an element of the oxide, the nitride or the oxynitride material is selected from but not limited to a group consisting of Mg, B, Al, Ca, Sr, La, Ti, Hf, V, Ta, Cr, W, Ru, Cu, In, Si and Eu;
or the nonmagnetic spacer layer is made of a metal or an alloy, and an element of the metal or alloy is selected from but not limited to a group consisting of Cu, Ag, Au, Al, Pt, Ta, Ti, Nb, Os, Ru, Rh, Y, Mg, Pd, Cr, W, Mo and V;
nonmagnetic spacer layer is made of but not limited to SiC, C or a ceramic material.

9. The magnetic tunnel junction device, as recited in claim 5, wherein:
an electrode material is a metal material or an alloy material selected from but not limited to a group consisting of Li, Mg, Al, Ca, Sc, Ti, V, Mn, Cu, Zn, Ga, Ge, Sr, Y, Zr, Nb, Mo, Tc, Ru, Rh, Pd, Ag, Cd, In, Sn, Sb, Ba, Hf, Ta, W, Re, Os, Ir, Pt, Au, Tl, Pb, Bi, Po, La, Ce, Pr, Nd, Pm, Sm, Eu, Gd, Tb, Dy, Ho, Er, Tm and Yb;
or the electrode material is a carbon-based conductive material selected from but not limited to graphite, carbon nanotubes or bamboo charcoal.

10. A magnetic random access memory based on a synthetic antiferromagnetic pinned layer, comprising:
an electric-field-assist-controlled magnetic tunnel junction device, which comprises a free magnetic layer, a pinned magnetic layer based on a synthetic antiferromagnetic device, and a nonmagnetic barrier layer arranged therebetween; wherein magnetization directions of the pinned magnetic layer based on the synthetic antiferromagnetic device and the free magnetic layer are outwardly perpendicular or parallel to interface; the synthetic antiferromagnetic device enhances antiferromagnetic coupling by electric field control;
the magnetic random access memory further comprises a pair of parallel electrode plates which generate an electric field, wherein the parallel electrode plates are arranged at both ends of the magnetic tunnel junction; an insulating layer is provided between the parallel electrode plates and electrodes; the parallel electrode plates generate the electric field with an external power source; the synthetic antiferromagnetic device enhances the antiferromagnetic coupling of the pinned layer under the electric field.
